(19) United States
(12) Patent Application Publication
(10) Pub. No.: US 2009/0108740 A1
(43) Pub. Date: Apr. 30, 2009

(54) Organic light emitting diode display

(76) Inventors: Eun-Ah Kim, Suwon-si (KR); Jeong-No Lee, Suwon-si (KR)

Correspondence Address: ROBERT E. BUSHNELL & LAW FIRM, 2029 K STREET NW, SUITE 600, WASHINGTON, DC, 20006-1004, US

(21) Appl. No.: 12/213,458

(22) Filed: Jun. 19, 2008

(30) Foreign Application Priority Data
Oct. 24, 2007 (KR) 10-2007-0107222

(51) Int. Cl. H01L 27/32

(52) U.S. Cl. 313/504

(57) ABSTRACT

An organic light emitting diode (OLED) display includes a first substrate, a second substrate, a sealing member, wire patterns, and a planarization layer. The first and second substrates face each other. The sealing member is disposed between the first substrate and the second substrate for sealing a space between the first substrate and the second substrate. The wire patterns are formed on at least one of the first and second substrates. The planarization layer is disposed between the wire patterns and is connected to the sealing member.

### CLAIM OF PRIORITY

This application makes reference to, incorporates the same herein, and claims all benefits accruing under 35 U.S.C. §119 from an application earlier filed in the Korean Intellectual Property Office on 24 Oct. 2007 and there duly assigned Serial No. 10-2007-0107222.

### BACKGROUND OF THE INVENTION

1. Field of the Invention

The present invention relates to an organic light emitting diode (OLED) display. More particularly, the present invention relates to a sealing structure of an organic light emitting diode (OLED) display.

2. Description of the Related Art

Among various display panels for a display device, a display panel using an organic light emitting diode (OLED) has been receiving attention according to the abrupt advance of semiconductor technology.

An active matrix type of OLED display using an organic light emitting diode includes a plurality of pixels arranged on a substrate in a matrix form and thin film transistors (TFT) disposed at each of the pixels, thereby independently controlling each of the pixels through the thin film transistors.

Meanwhile, an OLED display may be formed in a sealing structure in which an encapsulation substrate is sealed on a substrate, on which thin film transistors and organic light emitting diodes are formed. In more detail, the encapsulation substrate adheres to the substrate by applying a sealing material along the edge of the substrate, disposing the encapsulation substrate on the substrate, and hardening the sealing material by radiating ultraviolet (UV) rays.

In such a process, wire patterns elongated from the organic light emitting diodes are formed on a predetermined part of the substrate for electrically connecting an external device to the organic light emitting diodes. In general, the wire patterns protrude from the substrate.

When the substrate and the encapsulation substrate are sealed, the wire patterns might be coated with the sealing material. In this case, the coating state of the sealing material on the protruding wire patterns could deteriorate, and thus, areas around the wire patterns are not perfectly sealed.

The life-span and the reliability of an OLED display deteriorate by such a sealing defect.

The above information disclosed in this Background section is only for enhancement of understanding of the background of the invention and therefore it may contain information that does not form the prior art that is already known in this country to a person of ordinary skill in the art.

### SUMMARY OF THE INVENTION

The present invention has been made in an effort to provide an organic light emitting diode (OLED) display having advantages of having good sealing of a substrate and an encapsulation substrate by minimizing a step difference between a substrate and wire patterns, which is made by the wire patterns formed on the substrate.

An exemplary embodiment of the present invention provides an organic light emitting diode (OLED) display including first and second substrates, a sealing member, wire patterns, and a planarization layer. The first and second substrates face each other, and the sealing member is disposed between the first substrate and the second substrate for sealing a space between the first substrate and the second substrate. The wire patterns are arranged on the first substrate, and the planarization layer is disposed between the wire patterns and is connected to the sealing member.

The height of the planarization layer may be the same as the heights of the wire patterns.

The height of the planarization layer may be higher than the heights of the wire patterns, and a difference between the height of the planarization layer and the heights the wire patterns may be smaller than about 0.2 μm.

The first substrate may include a light emitting area and a non-light-emitting area, and the planarization layer may extend from the light emitting area to the non-light-emitting area.

The wire patterns and the planarization layer may be disposed between the sealing member and the first substrate.

The planarization layer may include an organic insulating material.

The OLED display may further includes a semiconductor layer, a gate insulating layer formed on the semiconductor layer, a gate electrode formed on the gate insulating layer, an interlayer insulating layer formed on the gate electrode, a source electrode and a drain electrode formed on the interlayer insulating layer, and a passivation layer formed on the source and the drain electrodes. The planarization layer may include a material identical to the material of the interlayer insulating layer or the material of the passivation layer.

The OLED display according to an exemplary embodiment of the present invention includes the planarization layer formed on the substrate to cover the wire patterns exposed at one side of the substrate. Therefore, the sealing member can be uniformly applied on the substrate by minimizing a step difference made by the wire patterns. Accordingly, the OLED display can be effectively protected from moisture and oxygen while perfectly sealing the substrate and an encapsulation substrate.

### BRIEF DESCRIPTION OF THE DRAWINGS

A more complete appreciation of the invention, and many of the attendant advantages thereof, will be readily apparent as the same becomes better understood by reference to the following detailed description when considered in conjunction with the accompanying drawings in which like reference symbols indicate the same or similar components, wherein:

FIG. 1 is an exploded perspective view of an organic light emitting diode (OLED) display according to an exemplary embodiment of the present invention.

FIG. 2 is a partial sectional view of FIG. 1 taken along the line II-II.

FIG. 3A to FIG. 3D are partial sectional views for describing a method for manufacturing an organic light emitting diode (OLED) display according to an exemplary embodiment of the present invention.

FIG. 4A to FIG. 4C are partial sectional views for describing a method for manufacturing an organic light emitting diode (OLED) display according to another exemplary embodiment of the present invention.

### DETAILED DESCRIPTION OF THE EMBODIMENTS

In the following detailed description, only certain exemplary embodiments of the present invention have been shown and described, simply by way of illustration. As those skilled in the art would realize, the described embodiments may be modified in various different ways, all without departing from the spirit or scope of the present invention.

Accordingly, the drawings and description are to be regarded as illustrative in nature and not restrictive. Also, like reference numerals designate like elements throughout the specification.

In addition, in the drawings, the thickness of layers, films, panels, regions, etc. are exaggerated for clarity. It will be understood that when an element such as a layer, film, region or substrate is referred to as being “on” another element, it can be directly on the other element or intervening elements may also be present. In contrast, when an element is referred to as being “directly on” another element, there are no intervening elements present.

Throughout this specification and the claims that follow, when it is described that an element is “coupled” to another element, the element may be “directly coupled” to the other element or “electrically coupled” to the other element through a third element. In addition, unless explicitly described to the contrary, the word “comprises” and variations such as “comprises” and “comprising” will be understood to imply the inclusion of stated elements but not the exclusion of any other elements.

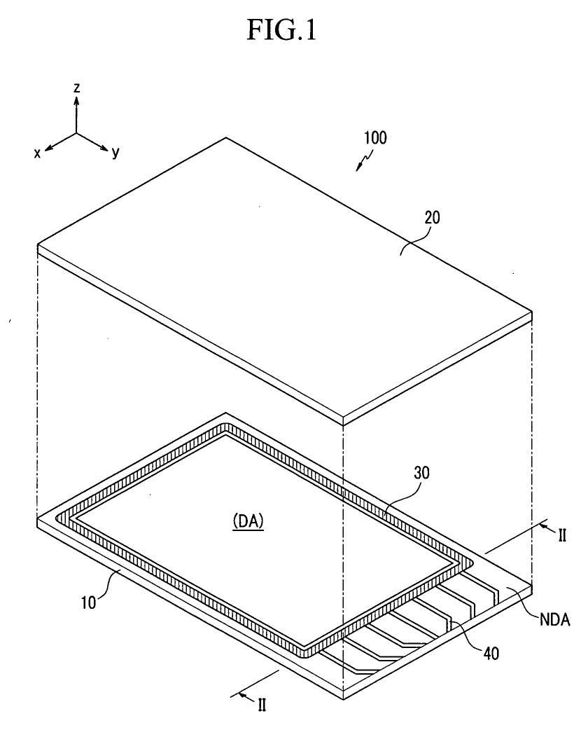

FIG. 1 is an exploded perspective view illustrating an organic light emitting diode (OLED) display 100 according to an exemplary embodiment of the present invention. Referring to FIG. 1, the OLED display 100 includes a first substrate 10, a second substrate 20, and a sealing member 30.

The first substrate 10 may be made of an insulating material or a metallic material. For the insulating material, glass or plastic may be used. For the metallic material, stainless using steel (SUS) may be used.

The first substrate 10 includes a light emitting area DA for emitting light and a non-light-emitting area NDA disposed at the periphery of the light emitting area DA. If the OLED display 100 has an active matrix structure, the light emitting area DA includes a plurality of organic light emitting diodes and thin film transistors for driving the organic light emitting diodes. The non-light-emitting area NDA includes wire patterns 40 that extend from scan lines or data lines that are formed at the light emitting area DA. The wire patterns 40 are electrically connected to a driving integrated circuit (IC) or a flexible printed circuit board (FPCB).

The second substrate 20 faces the first substrate 10, and is coupled to the first substrate 10 by the sealing member 30 disposed between the first substrate 10 and the second substrate 20. The sealing member 30 may be disposed along the edges of the first substrate 10 and the second substrate 20. Here, the sealing member 30 is also disposed on the wire patterns 40. According to the arrangement of the sealing member 30, the wire patterns 40 extend from the light emitting area DA to the non-light-emitting area NDA under the sealing member 30.

The sealing member 30 may be formed at the non-light-emitting area (NDA) in a shape of a tape in the present exemplary embodiment. The second substrate 20 seals organic light emitting diodes formed on the first substrate 10.

The second substrate 20 may be made of transparent glass. However, the present invention is not limited thereto. Materials for the first substrate and the second substrate may vary according to a light emitting direction of an organic light emitting diode (OLED) display.

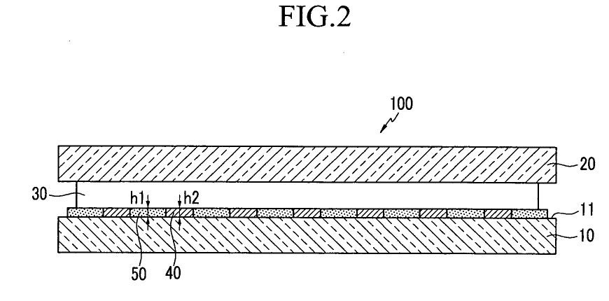

FIG. 2 is a cross-sectional view of FIG. 1 taken along the line II-II. Referring to FIG. 2, wire patterns 40 are arranged at a predetermined interval on a top surface 11 of the first substrate 10.

A planarization layer 50 is formed between two of the wire patterns 40. The planarization layer 50 fills spaces between two of the wire patterns 40 such that a step difference between the wire patterns and the first substrate 10 is not formed.

A height (or thickness) h1 of the planarization layer 50 is substantially the same as or higher than a height h2 of the wire pattern 40. In the present exemplary embodiment, the height h1 of the planarization layer 50 is substantially the same as the height h2 of the wire pattern 40, as shown in FIG. 2.

When the planarization layer 50 is formed to have a greater height than that of the wire pattern 40, it is preferable that the height difference between the planarization layer 50 and the wire pattern 40 is less than 0.2 μm.

If the height difference of the wire pattern and the planarization layer is greater than 0.2 μm, the sealing member 30 may be exfoliated such that it does not perfectly seal the space between the first substrate 10 and the second substrate 20, because the sealing member 30 is not applied uniformly around the wire patterns 40 and the planarization layer 50.

The planarization layer 50 may be made of an insulating material to prevent a short circuit between the wire pattern 40 and the planarization layer 50. Particularly, the planarization layer 50 may be made of an organic insulating material having good characteristics of preventing the penetration of moisture and oxygen, because a predetermined part of the planarization layer 50 may be exposed to the outer block of the sealing member 30. For example, the planarization layer 50 may be formed by extending a selected material among insulating layers formed on a light emitting area of the first substrate 10. Also, the planarization layer may be formed using an additional insulating material.

In the exemplary embodiment, the planarization layer 50 is formed by at least one of the insulating layers of the light emitting area DA.

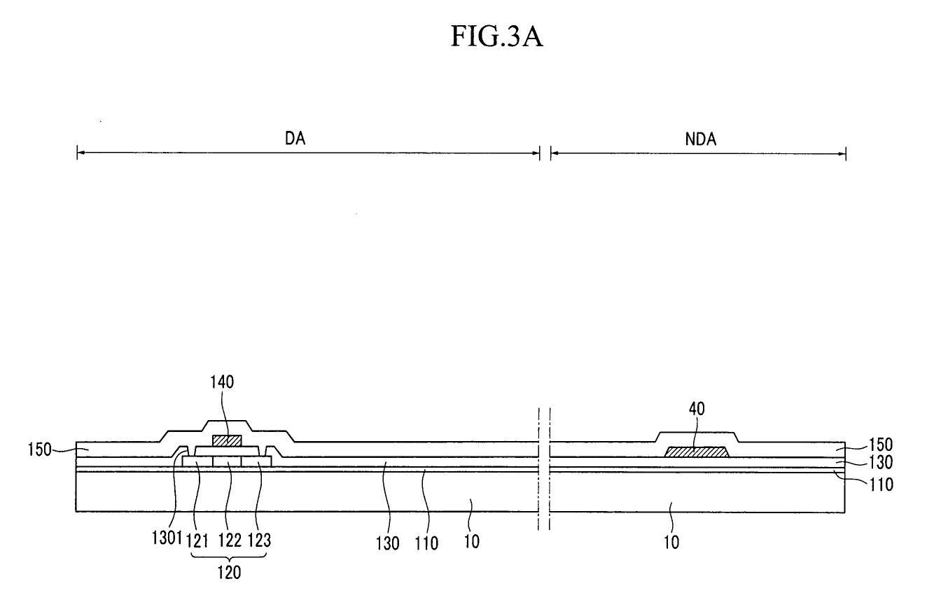

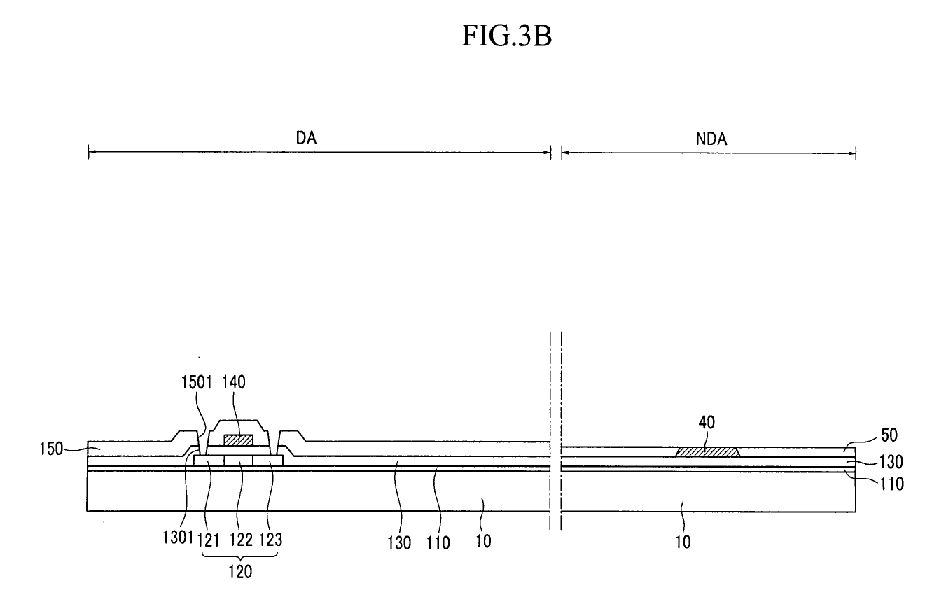

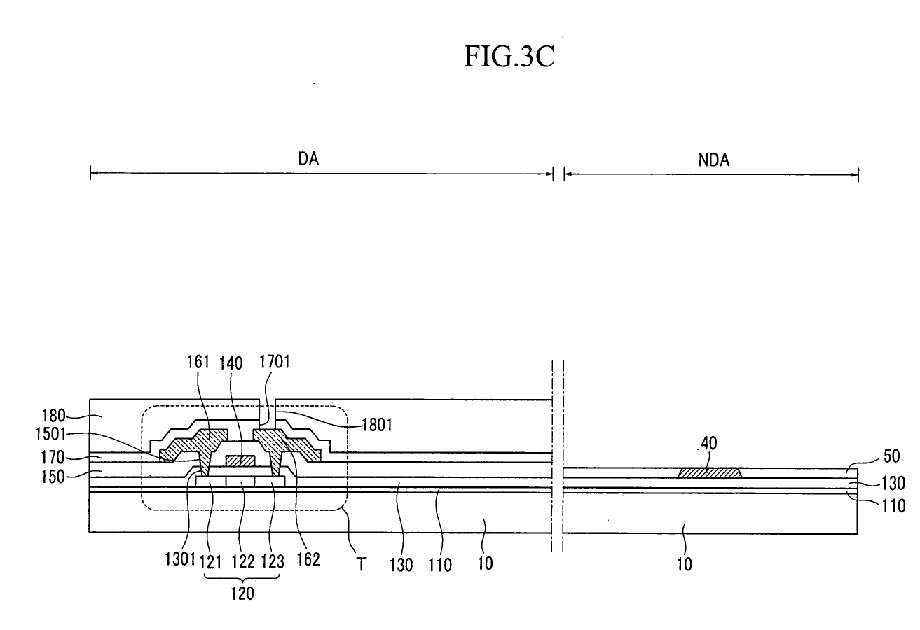

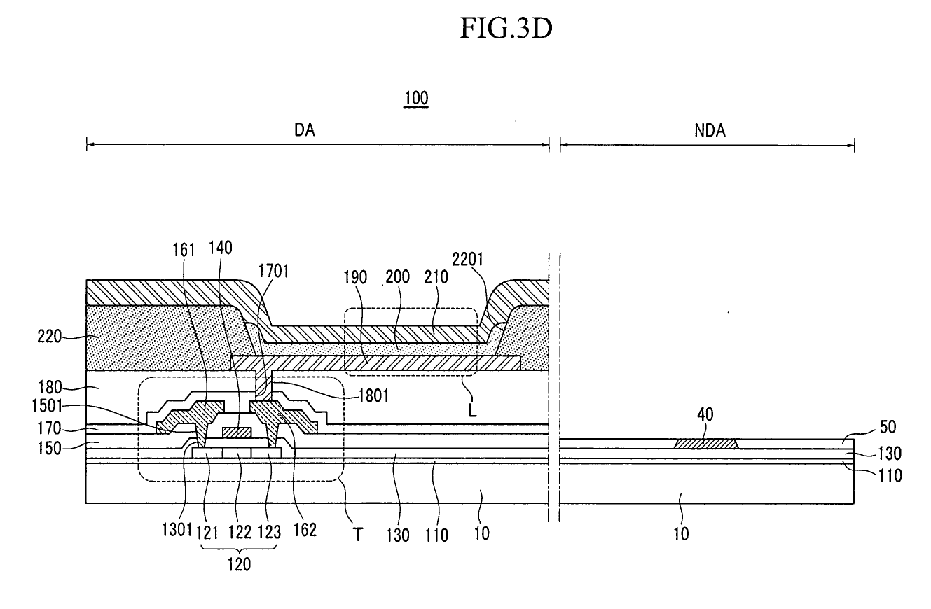

FIG. 3A to FIG. 3D are partial sectional views for describing a method for manufacturing an organic light emitting diode (OLED) display according to an exemplary embodiment of the present invention. That is, FIG. 3A to FIG. 3D show a magnified view of a predetermined part of a light emitting area DA and a non-light-emitting area NDA of FIG. 1.

Referring to FIG. 3A, a buffer layer 110 is formed on a first substrate 10 having a light emitting area DA and a non-light-emitting area NDA. The buffer layer 110 prevents impurities from being diffused when an active layer 120 is formed. For example, the buffer layer 110 may be made of a silicon nitride layer or a stacked layer of silicon nitride and silicon oxide.

Then, an active layer 120 is formed on the light emitting area DA of the first substrate 10. Here, the active layer 120 includes a source area 121, a drain area 123, and a channel area 122 for connecting the source area 121 and the drain area 123.

A gate insulating layer 130 is formed on the buffer layer 110 of the light emitting area DA and the non-light-emitting area NDA to cover the active layer 120. A first contact hole 1301 is formed at a predetermined portion of the gate insulating layer 130.

A gate electrode 140 is formed on the active layer 120 at the light emitting area DA with the gate insulating layer 130 interposed therebetween. Also, wire patterns 40 are formed in the non-light-emitting area NDA using the same material as that of the gate electrode 140. Here, the gate electrode 140 may be made of one selected from the group consisting of, for example, MoW, Al, Cr, and Al/Cr.

An interlayer insulating layer 150 is formed on the gate insulating layer 130 in the light emitting area DA and the non-light-emitting area NDA to cover the gate electrode 140 and the wire pattern 40.

Referring to FIG. 3B, a second contact hole 1501 is formed by etching a predetermined portion of the interlayer insulating layer 150 of the light emitting area DA. Simultaneously, a predetermined part of the interlayer insulating layer 150 is etched.

Here, the amount of etched interlayer insulating layer 150 in the non-light-emitting area (NDA) can be adjusted to be sufficient to make the height of the interlayer insulating layer 150, which remains on the substrate 10 after etching, substantially the same as the height of the wire pattern 40.

As a result, the source area 121 and the drain area 123 of the light emitting area DA are exposed through the first and second contact holes 1301 and 1501, and a planarization layer 50 is formed to fill spaces between the wire patterns 40 and other wire patterns (not shown) in the non-light-emitting area NDA in order to make the heights of the wire patterns 40 identical. That is, the planarization layer 50 may be made of the same material as that of the interlayer insulating layer 150 of the light emitting area DA.

Referring to FIG. 3C, a source electrode 161 and a drain electrode 162 are formed on the interlayer insulating layer 150 of the light emitting area DA, and the source electrode 161 and the drain electrode 162 are electrically connected to the exposed source and drain areas 121 and 123 through the first and second contact holes 1301 and 1501.

The source electrode 161 and drain electrode 162 may be made of metal, for example Ti/Al or Ti/Al/Ti. As a result, a thin film transistor T, which includes the active layer 120, the source electrode 161, the drain electrode 162, and the gate electrode 140, is formed.

A passivation layer 170 and a planarization layer 180 are sequentially formed to cover the thin film transistor T of the light emitting area DA. Here, first and second via holes 1701 and 1801 are formed in the passivation layer 170 and the planarization layer 180 to expose a predetermined part of the drain electrode 162.

Referring to FIG. 3D, a first pixel electrode 190, an organic emission layer 200, and a second pixel electrode 210 are sequentially formed on the planarization layer 180 of the light emitting area DA.

The first pixel electrode 190 is electrically connected to the drain electrode 162 of the thin film transistor T through the first and second via holes 1701 and 1801. Also, the first pixel electrode 190 is electrically isolated from a first pixel electrode (not shown) of an adjacent pixel by a pixel defining layer 220. The organic emission layer 200 is formed on the first pixel electrode 190 through an opening 2201 formed at the pixel defining layer 220. The second pixel electrode 210 is formed on the organic emission layer 200 to cover a front surface of the light emitting area DA. As a result, an organic light emitting diode L, which includes the first pixel electrode 190, the organic emission layer 200, and the second pixel electrode 210, is formed.

In the described exemplary embodiment, the wire pattern 40 is made of the same material as that of the gate electrode 140. However, the wire pattern may be made of the same material as that of the source electrode and the drain electrode.

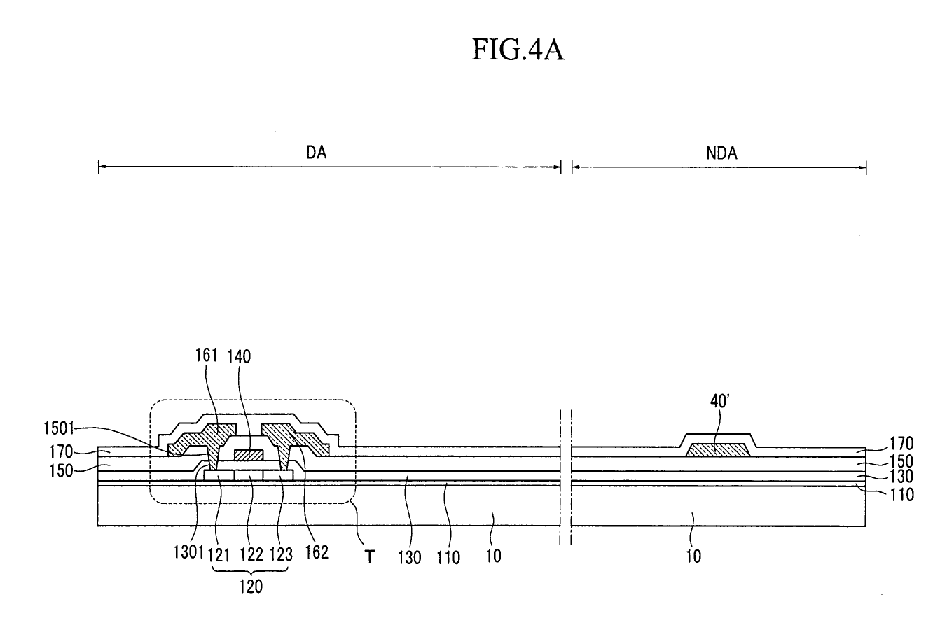

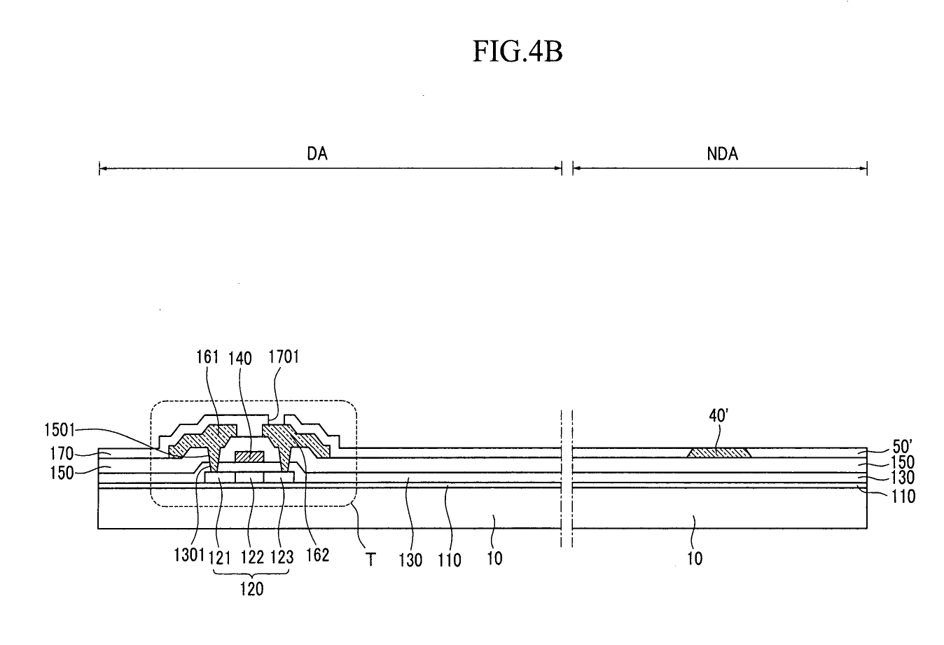

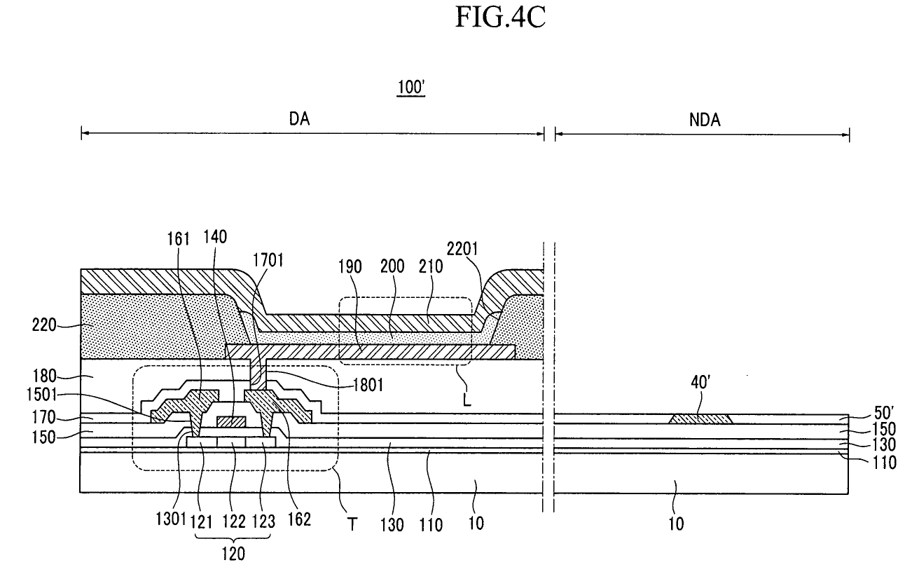

FIG. 4A to FIG. 4C are partial sectional views for describing a method for manufacturing an organic light emitting diode (OLED) display 100′ according to another exemplary embodiment of the present invention. In FIG. 4A to FIG. 4C and FIG. 3A to FIG. 3D, like reference numerals designate like constituent elements. For convenience, detailed descriptions of the same constituent elements are omitted.

Referring to FIG. 4A, a buffer layer 110, a gate insulating layer 130, and an interlayer insulating layer 150 of a light emitting area DA are identically formed on the substrate 10 of a non-light-emitting area NDA in a process of forming a thin film transistor T of a light emitting area DA.

Then, source and drain electrodes 161 and 162 are formed on the interlayer insulating layer 150 of the light emitting area DA. A wire pattern 40′, made of the same material as that of the source and drain electrodes 161 and 162, is formed on the interlayer insulating layer of the non-light-emitting area NDA.

A passivation layer 170 is formed to cover the thin film transistor T of the light emitting area DA and the wire pattern 40′ of the non-light-emitting area NDA.

Referring to FIG. 4B, a first via hole 1701 is formed to expose a predetermined part of the drain electrode 162 by etching a predetermined part of the passivation layer 170 of the light emitting area DA. Simultaneously, the passivation layer 170 of the non-light-emitting area NDA is also etched to form a space between the wire pattern 40′ and another wire pattern (not shown). As a result, a planarization layer 50′ is formed between the wire patterns to have a height substantially equivalent to the height of the wire pattern. As described above, the planarization layer 50′ may be formed using the same material as that of the passivation layer 170 of the light emitting area DA.

Referring to FIG. 4C, a planarization layer 180 is formed on the passivation layer 170 of the light emitting area DA, and a second via hole 1801 is formed corresponding to the first via hole 1701. Since remaining fabricating processes are identical to those described for FIG. 3D, detailed descriptions thereof are omitted.

In these present exemplary embodiments, the planarization layers 50 and 50′ have a single layer structure and are made of the same material as that of the interlayer insulating layer or the passivation layer. However, the planarization layer may be formed as a multilayered structure according to need.

Also, it is preferable to use an organic insulating material to form the planarization layers 50 and 50′ to prevent the penetration of moisture or oxygen because the planarization layers are exposed to the outside of the sealing member.

Furthermore, the wire pattern may be formed at the first substrate, the second substrate, or the first and second substrates. Here, the planarization layer may be formed between the wire patterns.

While this invention has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

What is claimed is:

1. An organic light emitting diode (OLED) display comprising:
a first substrate and a second substrate facing each other;
a sealing member disposed between the first substrate and the second substrate for sealing a space between the first substrate and the second substrate;
a plurality of wire patterns arranged on the first substrate; and
a planarization layer disposed between two of the wire patterns and connected to the sealing member.

2. The OLED display of claim 1, wherein the height of the planarization layer is substantially the same as the heights of the wire patterns.

3. The OLED display of claim 1, wherein the height of the planarization layer is higher than the heights of the wire patterns, and a difference between the height of the planarization layer and the heights of the wire patterns is smaller than about 0.2 μm.

4. The OLED display of claim 1, wherein the first substrate includes a light emitting area and a non-light-emitting area, and the planarization layer extends from the light emitting area to the non-light-emitting area.

5. The OLED display of claim 1, wherein both of the wire patterns and the planarization layer are disposed between the sealing member and the first substrate.

6. The OLED display of claim 1, wherein the planarization layer includes an organic insulating material.

7. The OLED display of claim 1, further comprising:
a semiconductor layer;
a gate insulating layer formed on the semiconductor layer;
a gate electrode formed on the gate insulating layer;
an interlayer insulating layer formed on the gate electrode;
a source electrode and a drain electrode formed on the interlayer insulating layer; and
a passivation layer formed on the source and the drain electrodes, wherein the planarization layer includes a material identical to the material of the interlayer insulating layer or the material of the passivation layer.

8. An organic light emitting diode (OLED) display comprising:
a first substrate;
a second substrate facing the first substrate, the first substrate including a light emitting area for emitting light and a non-light-emitting area
a sealing member disposed between the first substrate and the second substrate and being disposed to enclose the light emitting area;
a plurality of wire patterns arranged between the first substrate and the second substrate, the wire patterns extending from the light emitting area to the non-light-emitting area; and
a planarization layer disposed between two of the wire patterns.

9. The OLED display of claim 8, wherein a thickness of the planarization layer is substantially the same as a thickness of the wire patterns.

10. The OLED display of claim 8, wherein a thickness of the planarization layer is larger than a thickness of the wire patterns, and a difference between the thickness of the planarization layer and the thickness of the wire patterns is smaller than about 0.2 μm.

11. The OLED display of claim 8, wherein both of the wire patterns and the planarization layer are formed on the first substrate.

12. The OLED display of claim 11, wherein the sealing member is disposed between the second substrate and the planarization layer.
